(19) United States
(12) Patent Application Publication
(10) Pub. No.: US 2024/0202110 A1
(43) Pub. Date: Jun. 20, 2024

(54) APPARATUSES, SYSTEMS, AND METHODS FOR MEMORY REFRESH WATCHDOG

(71) Applicant: MICRON TECHNOLOGY, INC., BOISE, ID (US)

(72) Inventors: Rainer Bonitz, Bruckmuehl (DE); Aaron P. Boehm, Boise, ID (US)

(73) Assignee: MICRON TECHNOLOGY, INC., BOISE, ID (US)

(21) Appl. No.: 18/512,875

(22) Filed: Nov. 17, 2023

Related U.S. Application Data
(60) Provisional application No. 63/387,816, filed on Dec. 16, 2022.

(51) Int. Cl. G06F 12/02

(52) U.S. Cl. CPC G06F 12/023

(57) ABSTRACT

Apparatuses, systems, and methods for a memory refresh watchdog circuit. A memory may include a temperature sensor which sets a value of a refresh multiplier in a mode register. The memory includes a refresh watchdog circuit which determines an expected rate of refresh commands based on a current value of the refresh multiplier. The refresh watchdog circuit measures a rate at which refresh commands are received from a memory controller and compares the measured rate to the expected rate. For example, the refresh watchdog circuit may set a threshold based on the value of the refresh multiplier. The refresh watchdog circuit may change a count value each time a refresh command is received and compare the count value to the threshold. If the count value is less than the threshold, then the refresh watchdog circuit may determine that not enough refresh commands have been received.

### CROSS-REFERENCE TO RELATED APPLICATIONS

This application claims the filing benefit of U.S. Provisional Application No. 63/387,816, filed Dec. 16, 2022. This application is incorporated by reference herein in its entirety and for all purposes.

### BACKGROUND

This disclosure relates generally to semiconductor devices, and more specifically to semiconductor memory devices. In particular, the disclosure relates to volatile memory, such as dynamic random access memory (DRAM). Information may be stored on individual memory cells of the memory as a physical signal (e.g., a charge on a capacitive element). The memory may be a volatile memory, and the physical signal may decay over time (which may degrade or destroy the information stored in the memory cells). It may be necessary to periodically refresh the information in the memory cells by, for example, rewriting the information to restore the physical signal to an initial value.

Different conditions may change the rate at which information decays in the memory cells. For example, an increased temperature of the memory may increase a rate of information decay. It may be important to take such conditions into account when setting a rate of refresh operations, and to ensure that the refresh operations are being performed at an appropriate rate.

### BRIEF SUMMARY OF THE INVENTION

In at least one aspect, the present disclosure relates to an apparatus which includes a command counter circuit, a threshold determination circuit, and a comparator circuit. The command counter circuit counts a first quantity of refresh commands. The threshold determination circuit sets a threshold quantity of target refresh commands based on a refresh multiplier value. The comparator circuit receives the first quantity from the command counter, receives the threshold quantity from the threshold determination circuit, compares the first quantity to the threshold quantity, and sets a state of a fault flag based at least in part on the comparison.

The command counter circuit may count the first quantity of refresh commands performed within a first time period, and the threshold determination circuit may store the second quantity of target refresh commands performed within the first time period, where the first time period may be based at least in part on a timer circuit. The threshold determination circuit may calculate the threshold quantity of target refresh commands by dividing the constant value by the refresh multiplier value. The threshold determination circuit may include a table which maps the refresh multiplier value to the threshold quantity of target refresh commands.

The command counter circuit and the threshold determination circuit may be reset by a preset signal from a timer circuit. The refresh multiplier value may be based at least in part on a temperature of a memory device comprising the apparatus. The apparatus may include a pin which to couples the apparatus to an external controller. The comparator circuit may provide a real time flag to the pin based at least in part on the comparison.

In at least one aspect, the present disclosure relates to a memory which includes a mode register and a refresh watchdog circuit. The mode register includes a first register and a second register, the first register stores a refresh multiplier value, where the refresh multiplier value is based at least in part on a temperature of the memory, and the second register stores a fault flag. The refresh watchdog circuit receives the refresh multiplier value from the mode register, determines a threshold value based on the refresh multiplier value, receives and counts a quantity of refresh commands, compares the count of the one or more refresh commands to the threshold value, and set a state of the fault flag based at least in part on the comparison.

The memory may also include a timer circuit which provides a first timing signal and a second timing signal to the refresh watchdog circuit, where a first time period includes a time between the first timing signal and the second timing signal, and where the refresh watchdog circuit receives and counts the quantity of refresh commands within the first time period. The memory may also include an oscillator circuit which provides a clock signal to the timer circuit, where the timer circuit providing the first timing signal and the second timing signal is based at least in part on the clock signal.

The refresh watchdog circuit may calculate the threshold value by dividing a constant value by the refresh multiplier value. The refresh watchdog circuit may determine the threshold value by accessing a table that maps the refresh multiplier value to the threshold value. The refresh multiplier value may be inversely proportional to a refresh rate. The refresh watchdog circuit may provide a real time flag to a pin based at least in part on the comparison.

In at least one aspect, the present disclosure relates to a memory controller which includes a refresh control circuit which provides a quantity of refresh commands at a rate based at least in part on a refresh multiplier value read from a memory. The refresh control circuit receives a fault signal from the memory if the rate does not match an expected rate by the memory.

The refresh control circuit may indicate an error responsive to the fault signal. The fault signal may be stored as a fault flag in a mode register of the memory, where the refresh control circuit is configured to periodically check the memory for the fault flag. The refresh control circuit may receive the fault signal from a pin of the memory.

In at least one aspect, the present disclosure relates to a method which includes receiving a refresh multiplier value, receiving and counting one or more refresh commands, comparing the count of the one or more refresh commands to a threshold value based on a refresh multiplier value, and setting a state of a fault flag based at least in part on the comparison.

The method may include receiving a first timing signal and a second timing signal, where a first time period comprises a time between the first timing signal and the second timing signal, and where receiving and counting the quantity of refresh commands occurs within the first time period. The method may include measuring a temperature of a memory and setting a value of the refresh multiplier based on the measured temperature.

The method may include calculating the threshold value by dividing a constant value by the refresh multiplier value. The method may include determining the threshold value by accessing a table that maps the refresh multiplier value to the threshold value. The refresh multiplier value may be inversely proportional to a refresh rate. The method may include providing a real time flag to a pin based at least in part on the comparison.

In at least one aspect, the present disclosure may relate to a method which includes reading a refresh multiplier value from a memory with a memory controller, providing refresh commands from the memory controller to the memory at a rate that is based at least in part on the refresh multiplier value, and receiving a fault signal from the memory if the rate does not match an expected rate by the memory.

The method may include indicating an error responsive to the fault signal. The method may include periodically checking a mode register of the memory for a fault flag. The method may include receiving a real time flag from a pin if the rate does not match an expected rate by the memory. The method may include changing the rate of providing the refresh commands responsive to receiving the fault signal.

### BRIEF DESCRIPTION OF THE DRAWINGS

FIG. 1 is a block diagram of a semiconductor device according to some embodiments of the disclosure.

FIG. 2 is a block diagram of a semiconductor device according to some embodiments of the disclosure.

FIG. 3 is a block diagram of a memory according to some embodiments of the disclosure.

FIG. 4 is a block diagram of a vehicle according to some embodiments of the disclosure.

FIG. 5 is a flowchart of a method according to some embodiments of the disclosure.

FIG. 6 is a flowchart of a method according to some embodiments of the disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a volatile memory device may be stored in memory cells (e.g., as a charge on a capacitive element), and may decay over time. The memory cells may be organized into rows (wordlines) and columns (bitlines) in each bank of a memory array. In order to prevent information from being lost or corrupted due to this decay, the memory may carry out refresh operations, such as auto-refresh operations, which may perform a sequence of refresh operations which cycle through the wordlines of the memory array. For example, the memory cells may be refreshed on a row-by-row basis. During a refresh operation, information may be rewritten to memory cells associated with the wordline to restore their initial states. The refresh operations may be performed on the wordlines of the memory in a sequence such that over a refresh cycle all wordlines are refreshed. For example, a controller of the memory may provide all-bank refresh (ABR) and/or per-bank refresh (PBR) commands, each of which causes the memory to perform one or more refresh operations.

The rate at which the refresh operations are performed (e.g., the rate at which refresh commands are issued) may be chosen to prevent the loss of information, ideally such that each memory cell is refreshed before the information stored in that memory cell is lost. The rate at which the refresh cycle is performed may be based on an expected fastest rate of information decay. However, certain conditions of the memory, such as the temperature, change the expected rate of information decay. For example, as temperature increases, the rate of information decay may generally increase. The memory includes a temperature sensor circuit, and stores a value which indicates a refresh rate based on the temperature. For example, the memory may include a refresh multiplier mode register, which has a value based on the readings from the temperature sensor. The controller reads the value and provides refresh commands (e.g., ABR) at a rate based on the value. Since receiving the refresh commands at the appropriate rate may be important to ensure the retention of data, it may be useful for the memory to determine if the controller is actually providing the refresh commands at an appropriate rate.

The present disclosure is drawn to memory refresh watchdog circuits. The memory includes a temperature sensor which sets a value of a refresh multiplier in the mode register. The memory includes a refresh watchdog circuit which determines an expected rate of refresh commands based on the current value of the refresh multiplier. The refresh watchdog circuit measures a rate at which refresh commands are received from the controller and compares the measured rate to the expected rate. For example, the refresh watchdog circuit may set a threshold based on the value of the refresh multiplier. The refresh watchdog circuit may change a count value each time a refresh command is received and compare the count value periodically to the threshold. If the count value is less than the threshold, then the refresh watchdog circuit may determine that not enough refresh commands have been received.

If the refresh watchdog circuit determines that the measured rate of refresh commands is less than the expected rate, the memory may set an alert flag (e.g., fault flag). In some embodiments, the memory may write the alert flag to a mode register. In some embodiments, the memory may provide a signal such as an alert signal (e.g., fault signal) to the controller to indicate that not enough refreshes are being performed. The controller may take various actions upon discovering that the memory has determined that the rate of refresh commands does not meet the expected refresh rate (e.g., either on reading the alert mode register and/or upon receiving a signal). For example, the controller may immediately check the refresh multiplier in the memory and adjust the rate accordingly, may initiate an error check of information stored in the memory, may increase a frequency at which the refresh multiplier is checked (and the refresh rate adjusted), may take other actions (e.g., alerting a user, ceasing operations, etc.), or combinations of these.

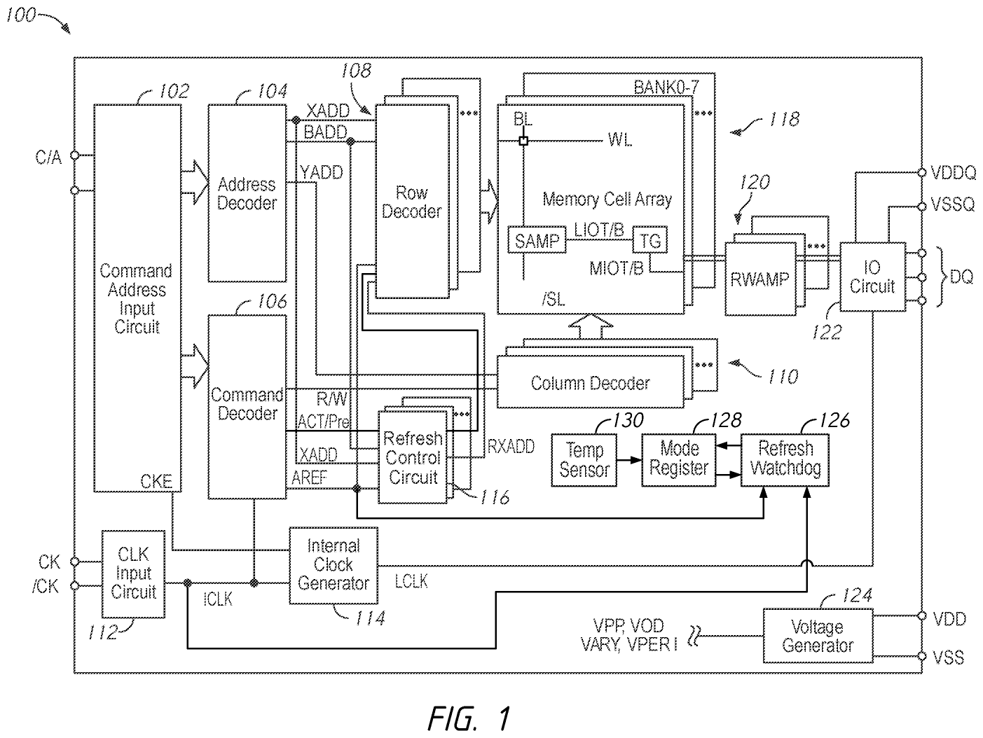

FIG. 1 is a block diagram of a semiconductor device according an embodiment of the disclosure. The semiconductor device 100 may be a semiconductor memory device, such as a DRAM device integrated on a single semiconductor chip.

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. For example, memories may include 4, 16, 32 more or fewer banks. Each memory bank includes a plurality of wordlines WL, a plurality of bitlines BL and/BL, and a plurality of memory cells MC arranged at intersections of the plurality of wordlines WL and the plurality of bitlines BL and/BL. The selection of the wordline WL is performed by a row decoder 108 and the selection of the bitlines BL and/BL is performed by a column decoder 110. In the embodiment of FIG. 1, the row decoder 108 includes a respective row decoder for each memory bank and the column decoder 110 includes a respective column decoder for each memory bank. The bitlines BL and/BL are coupled to a respective sense amplifier (SAMP). Read data from the bitline BL or/BL is amplified by the sense amplifier SAMP, and transferred to read/write amplifiers 120 over complementary local data lines (LIOT/B), transfer gate (TG), and complementary main data lines (MIOT/B). Conversely, write data outputted from the read/write amplifiers 120 is transferred to the sense amplifier SAMP over the complementary main data lines MIOT/B, the transfer gate TG, and the complementary local data lines LIOT/B, and written in the memory cell MC coupled to the bitline BL or /BL.

The semiconductor device 100 may employ a plurality of external terminals that include command and address (C/A) terminals coupled to a command and address bus to receive commands and addresses, and a CS signal, clock terminals to receive clocks CK and /CK, data terminals DQ to provide data, and power supply terminals to receive power supply potentials VDD. VSS, VDDQ, and VSSQ. The external terminals may be coupled to a controller (not shown in FIG. 1) which may operate the memory by providing various signals to the external terminals.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a wordline and a column command signal to select a bitline. The command decoder 106 also provides activation and pre-charge signals to the different banks of the memory. An activation signal ACT may indicate that a wordline in that bank should be activated, while a pre-charge signal Pre may indicate that the wordlines should be pre-charged (e.g., closed) in anticipation of a next activation command. In some embodiments, the ACT and Pre signals may share a signal line.

The device 100 may receive commands and addresses as part of an access operation such as a read operation. As part of the access operation, a row address and bank address received along with an activate command. As part of the access operation, a column address and bank address are received along with a read command. Responsive to the read operation, read data is read from memory cells in the memory array 118 corresponding to the row address and column address. The commands associated with the read operation are received by the command decoder 106, which provides internal commands so that read data from the memory array 118 is provided to the read/write amplifiers 120. Responsive to the activate command the row decoder 108 activates a wordline associated with the row address. While the row is active, memory cells along that row are coupled to sense amplifiers activated by the column decoder 110 responsive to the read command to read data out along the LIOT/B lines. The read data is output to outside from the data terminals DQ via the input/output circuit 122. The command decoder 106 may then provide a pre-charge command which may ‘close’ the active row.

The device 100 may receive commands and addresses as part of an access operation such as a write operation. As part of the write operation, a row address and bank address are received along with an activated command and a column address and bank address are received along with write data and a write command. Responsive to the write operation, write data supplied to the data terminals DQ is written to a memory cells in the memory array 118 corresponding to the row address and column address. The commands associated with the write operation are received by the command decoder 106, which provides internal commands so that the write data is received by data receivers in the input/output circuit 122. Responsive to the activate command the row decoder 108 activates a wordline associated with the row address. While the row is active, memory cells along that row are coupled to sense amplifiers activated by the column decoder 110 responsive to the write command to receive write data. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC. The command decoder 106 may then provide a pre-charge command which may ‘close’ the active row.

The device 100 may also perform refresh operations, responsive to internal signals (e.g., in a self-refresh mode) or responsive to refresh commands from the controller. For example, the controller may issue a refresh (e.g., an ABR) command, the memory device 100 may perform one or more refresh operations responsive to that refresh command as part of an refresh operation. For example, the memory device 100 may perform one or more CAS before RAS (CBR) refresh operations, targeted refresh operations, or combinations thereof responsive to each of the received refresh commands. The controller may issue refresh commands along the C/A bus to the C/A terminals of the memory, and the command decoder 106 may generate one or more internal signals (e.g., AREF) responsive to the command.

The refresh operations are used for periodic refreshes of data stored in memory array 119 (e.g., a DRAM capacitor array). Periodic refreshes of data may allow the memory cells of memory array 119 to retain their logic states, for example, by refreshing the level of charge in the capacitor. Without periodic refreshes of data, the capacitors would leak or otherwise lose their charge, and thus could cause errors in the device 100. Additionally, the memory cells may lose their charge at different rates depending on a temperature of the DRAM. For example, capacitors may lose their charge faster at high temperatures, and slower at low temperatures. As such, the memory cells may need to be refreshed more frequently at higher temperatures to retain the logic states of the memory cells. Similarly, the memory cells may be refreshed less frequently (e.g., to save power and/or to free up time for other operations) when the temperature is cooler without risking information loss.

A refresh window is a time period tREFW over which the memory device 100 expects to have all of its memory cells refreshed. A memory controller (not pictured) may provide one or more refresh commands to the device 100 within the refresh window to perform the refresh operations. For example, the memory controller may transfer 8192, or any other number, of refresh commands within the refresh window duration tREFW. The number of refresh commands issued during tREFW may be based on a number of refresh commands which refreshes the memory cells of the memory array 118. For example, if there are N total word lines, and each refresh command causes M word lines to be refreshed, then at least N/M commands may be expected within tREFW. The duration tREFW may have a default value which is device specific. The refresh window duration tREFW may be shorter in high temperatures, and longer in low temperatures. Since the number of refresh operations which need to be performed during tREFW, and thus the number of refresh commands received, may generally be constant, the change in tREFW may increase or decrease the rate at which the controller is expected to provide refresh commands.

The value of tREFW may be calculated using Equation 1:

$$t R E F W = REFRESH MULTIPLIER \times 32 ms \qquad ( 1 )$$

Refresh Multiplier may be a value stored in a mode register 128 (e.g., Mode Register 4) of the device 100. The value of the refresh multiplier may be based on a temperature of the device 100, a temperature outside the device 100, or combinations thereof. Or, if other memory device conditions or external conditions would have an impact on the best refresh multiplier, such conditions could be considered as well. The time 32 milliseconds (ms) may represent a standard or default refresh window duration corresponding to a normal temperature range. A temperature sensor 130 may update the value of the refresh multiplier in the mode register 128 (e.g., every 32 ms, or any other duration). In some cases, the temperature sensor 130 may be implemented as an on-die temperature controlled oscillator.

Table 1 details example LPDDR5 mode register information (refresh multiplier values), and their corresponding multiplier for Equation 1. As mentioned previously, higher multiplier values correspond to low temperatures and longer tREFW durations (e.g., a decreased rate of refreshes), while low multiplier values correspond to high temperatures and shorter tREFW durations (e.g., an increased rate of refreshes):

TABLE 1

| Mode Register Information | Multiplier |
|---|---|
| 00000B | Low temperature operating limit exceeded |
| 00001B | 8x |
| 00010B | 6x |
| 00011B | 4x |
| 00100B | 3.3x |
| 00101B | 2.5x |
| 00110B | 2x |
| 00111B | 1.7x |
| 01000B | 1.3x |
| 01001B | 1x |
| 01010B | 0.7x |
| 01011B | 0.5x |
| 01100B | 0.25x, no de-rating |
| 01101B | 0.25x, with de-rating |
| 01110B | 0.125x, no de-rating |
| 01111B | 0.125x, with de-rating |
| 11111B | High temperature operating limit exceeded |

For example, if the refresh multiplier has a value of 01011B in the mode register 128, the controller will be expected to provide the requisite number of refresh commands (e.g., 8192 ABR commands) within 0.5 times 32 ms, or 16 ms, to the device 100, according to Equation 1.

Various refresh command types (e.g., ABR, single-bank refresh or PBR) commands may be used within the duration tREFW (e.g., depending on memory type (e.g., DRAM type)).

In some cases, the tREFW refresh window may be considered a base requirement duration and may be unaffected by other refresh management requirements. For example. the controller may determine that additional refresh commands are required due to access patterns of the memory, external conditions, etc.

The refresh signal AREF is supplied to the refresh control circuit 116. In some examples, the refresh signal AREF may be generated responsive to the refresh command. The refresh control circuit 116 supplies one or more refresh row addresses RXADD to the row decoder 108 responsive to the refresh signal AREF. The row decoder 108 may refresh one or more wordlines WL indicated by the refresh row address RXADD. In some embodiments, the refresh address RXADD may represent a single wordline. In some embodiments, the refresh address RXADD may represent multiple wordlines, which may be refreshed sequentially or simultaneously by the row decoder 108. In some embodiments, the number of wordlines represented by the refresh address RXADD may vary from one refresh address to another. The refresh control circuit 116 may be controlled to change details of the refreshing address RXADD (e.g., how the refresh address is calculated, the timing of the refresh addresses, the number of wordlines represented by the address), or may operate based on internal logic.

The refresh control circuit 116 may selectively output a targeted refresh address (e.g., which specifies one or more victim address based on an aggressor) or an automatic refresh address (e.g., from a sequence of CBR addresses) as the refresh address RXADD. Based on the type of refresh address RXADD (and in some embodiments, one more additional signals indicating the type of operation), the row decoder 108 may perform a targeted refresh or CBR operation. The automatic refresh addresses may be from a sequence of addresses such that over a cycle of the sequence, all of the wordlines are refreshed. For example, a counter circuit may be used to increment or otherwise ‘count through’ possible row address values for RXADD. The refresh control circuit 116 may cycle through the sequence of CBR addresses at a rate determined by AREF. A refresh cycle may represent the CBR address generator refreshing each row of the memory (e.g., providing each value of the CBR address). In some embodiments, the CBR operations may generally occur with a timing such that the sequence of CBR addresses is cycled such that no information is expected to degrade in the time between CBR operations for a given wordline. In other words, CBR operations may be performed such that each wordline is refreshed at a rate faster than the expected rate of information decay.

The refresh control circuit 116 may also determine targeted refresh addresses which are addresses that require refreshing (e.g., victim addresses corresponding to victim rows) based on the access pattern of nearby addresses (e.g., aggressor addresses corresponding to aggressor rows) in the memory array 118. The refresh control circuit 116 may use one or more signals of the device 100 to calculate the targeted refresh address RXADD. For example, the refresh address RXADD may be a calculated based on the row addresses XADD provided along a row address bus by the address decoder 104.

The power supply terminals are supplied with power supply potentials VDD and VSS. The power supply potentials VDD and VSS are supplied to an internal voltage generator circuit 124. The internal voltage generator circuit 124 generates various internal potentials VPP, VOD, VARY, VPERI, and the like based on the power supply potentials VDD and VSS supplied to the power supply terminals. The internal potential VPP is mainly used in the row decoder 108, the internal potentials VOD and VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

In some examples, the memory 100 may include a refresh watchdog circuit 126. The refresh watchdog circuit 126 may receive one or more refresh commands (e.g., ABR commands and/or AREF signals generated responsive to those ABR commands) from a memory controller (not pictured). In some examples, the refresh watchdog circuit 126 may receive the one or more refresh commands via an AREF signal. The refresh watchdog circuit may count each of the refresh commands. The refresh watchdog circuit 126 may receive the refresh multiplier value from the mode register 128 (e.g., from MR4). Based on the refresh multiplier value, the refresh watchdog circuit 126 may determine a number of expected refresh commands within a time period. The number of expected refresh commands may be based on the refresh multiplier and a number of refresh commands which will refresh the memory cells of the array 118 (e.g., 8192 refresh commands). The refresh watchdog circuit may compare the counted number of refresh commands that were actually received, to the expected number of refresh commands, which may act as a threshold. If the counted number of refresh commands is less than the threshold number of refresh commands, the refresh watchdog circuit 126 may provide an alert signal. The alert signal may be used to set a state of an alert flag (e.g., set an alert flag in the mode register 128 to an active level), may be provided directly to the controller (e.g., over an alert pin), or the like, indicating that there is an error at the memory controller is not providing refresh commands at the expected rate. Detecting when the memory controller is not providing enough refresh commands within a time period allows for troubleshooting on the memory controller so that data in the memory cells in the memory array 119 is not lost due to insufficient refreshing at high temperatures.

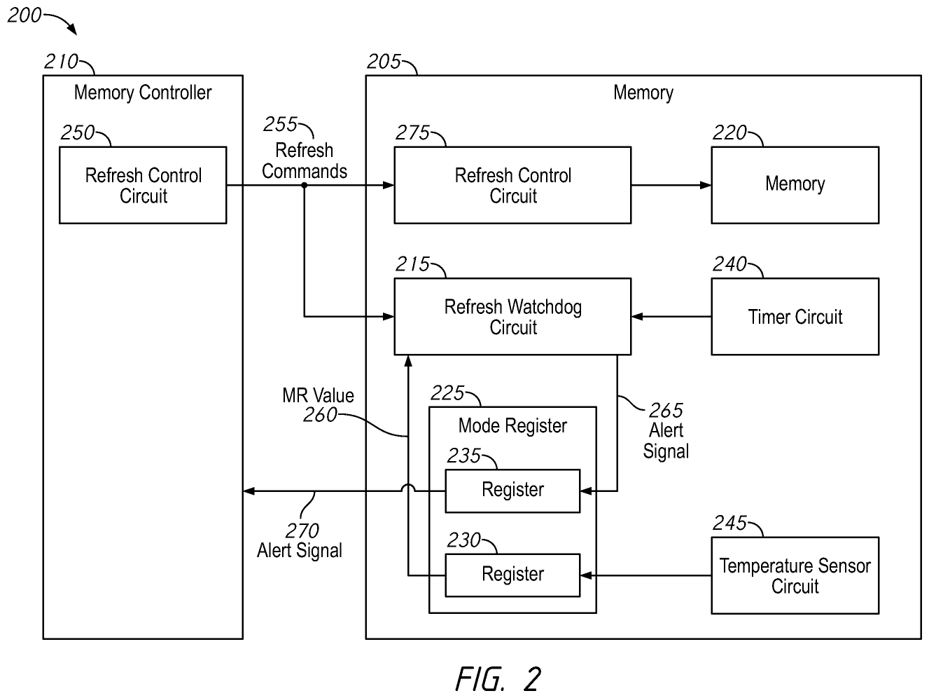

FIG. 2 is a block diagram of a semiconductor device according an embodiment of the disclosure. The semiconductor device 200 may include a memory 205 and a memory controller 210. In some examples, the memory 205 may include the memory 100, or the memory 100 may include the memory 205. The memory 205 may include a refresh watchdog circuit 215, a refresh control circuit 275, a memory array 220, a mode register 225, a register 230, a register 235, a timer circuit 240, a temperature sensor circuit 245, or any combination of these. In some examples, the memory controller 210 may include a refresh control circuit 250. In some examples, the memory array may correspond to the memory cell array 119. In some examples, the refresh watchdog circuit 215 may correspond to the refresh watchdog circuit 126. In some examples, the mode register 225 may correspond to the mode register 128. In some examples, the timer circuit 240 may provide a signal that corresponds to the signal ICLK, or an external clock signal. While this disclosure may discuss refresh commands, one having ordinary skill in the art would understand that any type of refresh commands (e.g., ABR commands, single-bank refresh commands or PBR commands) would be applicable to the present invention. ABR commands refresh all banks concurrently or within a short time period, while PBR commands refresh one bank at a time.

Mode register 225 may be a read-only DRAM integrated register, and the information stored by mode register 225 may include encoded DRAM integrated temperature sensor information, and in some cases, an optional offset. The encoded DRAM integrated temperature sensor information may include the refresh multiplier. Memory controller 210 may read the mode register 225 at a frequency determined by Equation 2:

$$TempGradient \times ( ReadInterval + t T S I + SysRespDisplay ) \leq 2 ° C . \qquad ( 2 )$$

Equation 2 may be an example for LPDDR5. Other DRAM memories may require a similar, but in some cases not identical, other formula.

The TempSensorInterval (tTSI) may be a maximum delay between internal updates of the mode register 225 (e.g., 32 ms, 4 ms, or any other value). The TempGradient may be a maximum temperature gradient experienced by the memory 205 at the temperature of interest. ReadInterval may be a time period between Register READs (e.g., of mode register 225) from the system. SysRespDelay may be a maximum response time from a Register READ (e.g., of mode register 225) to the system response.

Memory controller 210 may provide one or more refresh commands 255 to the memory 205 with timing based on a refresh window tREFW. Refresh control circuit may receive the refresh commands 255, and may refresh the memory array 220 based on the refresh commands 255. For example, if responsive to each refresh command M wordlines are refreshed, and there are N wordlines in the memory array 220, then N/M refresh commands may be expected each refresh cycle. For example, the memory controller may transfer 8192, or any other number, of refresh commands 255 to the memory 205 during the refresh window tREFW as part of a refresh cycle of the memory array 220.

The refresh watchdog circuit 215 may receive the refresh commands 255 from the controller 210. The refresh watchdog circuit 215 may count each of the refresh commands. In some examples, the refresh watchdog circuit 215 may count the refresh commands 255 during an interval based on a timing signal received from the timer circuit 240. For example, the timing signal may include an interrupt signal, and the timer circuit 240 may provide timing signals separated by a period of time (e.g., 32 ms). The refresh watchdog circuit 215 may count the number of refresh commands 255 received within the period of time. Responsive to the interrupt signal (e.g., every 32 ms) the refresh watchdog circuit 215 compares the count to a threshold (e.g., based off the refresh multiplier), and resets the count.

The refresh watchdog circuit 215 may receive a mode register value 260 from the mode register 225. In some examples, the refresh watchdog circuit 215 may receive (e.g., read) the mode register value 260 from the register 230 of mode register 225 at a frequency based on Equation 2. The frequency that the mode register 225 is read may be referred to as the ReadInterval. In some examples, the register 230 may be or may be referred to as mode register 4 (MR4). Register 230 may update at a frequency tTSI from Equation 2. For example, register 230 may receive temperature information from the temperature sensor circuit 245 and update the mode register value stored in the register 230.

Based on the mode register value 260, the refresh watchdog circuit 215 may receive a refresh multiplier value (e.g., using a table such as Table 1, or any other method). Using the refresh multiplier, the refresh watchdog circuit 215 may determine a number of expected refresh commands or threshold refresh commands received in the period between signals from the timer circuit 240 (e.g., within the period corresponding to the timer circuit 240, such as 32 ms). The refresh watchdog circuit 215 may use a table, an equation, or any other method, for determining the threshold number of refresh commands based on the refresh multiplier. As such, the determination of the threshold number of refresh commands and the counting of the received refresh commands are both with respect to the duration of the period between interrupt signals, or the counting interval, of the timer circuit 240. In this way, the refresh watchdog circuit 215 may be able to determine a threshold rate (e.g., expected number of received refresh commands during the timer period) and an actual rate (e.g., counted number of received refresh commands during the same timer period) of refresh commands received by the memory 205.

The refresh watchdog circuit 215 may compare the counted number of refresh commands that were actually received during the timer period, to the threshold number of refresh commands for the timer period. Said another way, the refresh watchdog circuit may compare the rate of received refresh commands to the threshold rate of refresh commands. If the counted number of refresh commands during the timer period is less than the threshold number of refresh commands for the timer period, or if the rate of received refresh commands is less than the threshold rate of refresh commands, the refresh watchdog circuit 215 may provide an alert signal 265. For example, responsive to the alert signal, the mode register 225 may set a state of an alert flag at register 235, indicating that there is an error at the memory controller 210 not providing enough refresh commands. In some cases, memory controller 210 may receive (e.g., read) the alert flag from register 235. In some other cases, the memory 205 may provide an alert signal 270 to the memory controller 210.

In some examples, the alert flag in the register 235 may be reset automatically after each register access (e.g., the state of the register 235 may be reset after the controller reads a state of the register 235). That is, the alert flag is stored until the controller 210 checks the register 235, and the flag is reset to an inactive value. A new alert signal from the refresh watchdog circuit 215 can once again set the alert flag again at the register 235.

The memory controller 210 may communicate with the memory 205 and may take various actions upon discovering that the memory has determined that the rate of refresh commands does not meet the expected refresh rate. The memory controller 210 may read a mode register value (refresh multiplier value) from register 230. The memory controller 210 may provide one or more refresh commands 255 to memory 205 at a rate based on the multiplier value. The controller 210 may determine a rate of refresh commands in a manner similar to the refresh watchdog circuit 215. For example, the controller 210 may decode the mode register value in accordance with Table 1, above.

The memory 205 may use various methods to communicate the alert signal 270 to the controller 210. In response, the memory controller 210 may receive the alert signal 270 from the memory 205. Additionally or alternatively, the memory controller 210 may receive a real time flag signal from the memory. In other words, the memory 205 may directly provide the alert signal 270 without waiting for the controller 210 to check the value. For example, the memory 205 may provide the alert signal along a pin which couples the memory 205 and controller 210. In some cases, the alert signal may be connected to an interrupt or alert input of the processor 420 that includes the memory controller. Additionally or alternatively, the memory controller 210 may read (e.g., receive, or check) the alert flag (e.g., fault flag) from register 235 (e.g., periodically). In some embodiments, the memory 205 may provide a generic alert signal, and the controller 210 may check various registers, such as register 235, which store error codes to determine what kind of alert was issued.

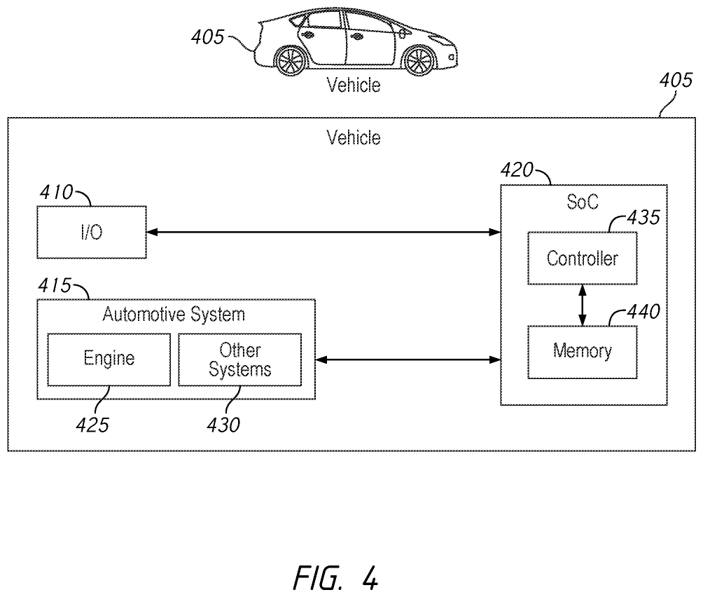

In response to determining that the rate of refresh commands does not meet the expected refresh rate, memory controller 210 may check the refresh multiplier in the memory 205 and adjust the rate of refresh commands 255 provided accordingly (e.g., a refresh window adjustment), may initiate an error check of information stored in the memory 205, may increase a frequency at which the refresh multiplier (e.g., at MR4) is checked (and the refresh rate adjusted), may check for bit errors and bit error corrections or new data load, may take other actions (e.g., alerting a user), or combinations of these. In some examples, memory controller 210 may control one or more operations of a vehicle, which may be described in further detail in at least FIG. 4. Detecting when the memory controller 210 may not be providing refresh commands 255 at a sufficient rate may allow for troubleshooting on the memory controller 210 so that data in the memory cells in the memory array 220 is not lost due to insufficient refreshing.

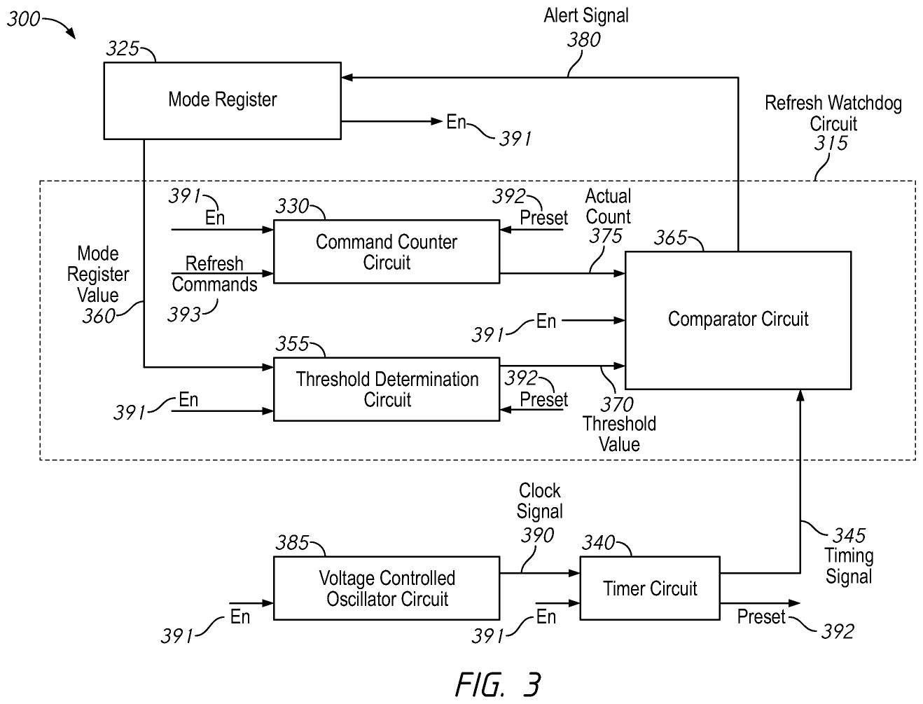

FIG. 3 is a block diagram of at least a portion of a memory 300 according an embodiment of the disclosure. The memory 300 may be or include memory 205, or memory 100. Refresh watchdog circuit 315 may be or include the refresh watchdog circuit 215 or the refresh watchdog circuit 126. The mode register 325 may be or include the mode register 225, or the mode register 128. The timer circuit 340 may be or include the timer circuit 240. While this disclosure may discuss refresh commands, one having ordinary skill in the art would understand that any other type of refresh commands (e.g., ABR commands, single-bank refresh commands or PBR commands) would be applicable to the present invention. The mode register 325, command counter circuit 330, threshold determination circuit 355, comparator circuit 365, voltage controller oscillator circuit 385, and timer circuit 340, may receive an enable signal 391 for activation. For example, the refresh watchdog circuit 315 may be an optional feature that is selectively enabled (e.g., based on a mode register). In some other implementations, the refresh watchdog circuit 315 may be permanently enabled or disabled in hardware (e.g., mask option) or by a test (e.g., trim) option. For example, based on a setting of mode register 325 (e.g., a bit in the mode register 325), the enable signal 391 for one or more of the command counter circuit 330, threshold determination circuit 355, comparator circuit 365, timer circuit 340, and voltage controlled oscillator circuit 385 may be either active or inactive.

A memory controller (not pictured) may provide one or more refresh commands to the memory 300. The command counter 330 may count each of the refresh commands 393 during a time interval which is based on the timer circuit 340. The command counter 330 may count in a first direction (e.g., up from zero), or may count in a second direction opposite the first direction (e.g., down from a value). The timer circuit 340 may provide a preset signal 392 to the command counter 330 (e.g., immediately after providing a timing signal 345 (e.g., Int32) to the comparator 365), and the preset signal 392 may reset the command counter 330 to zero. In this way, the count of refresh commands may represent the amount of commands between timing signals 345.

Threshold determination circuit 355 of the refresh watchdog circuit 315 may receive a mode register value 360 from the mode register 325. The mode register value 360 may be based on a temperature of the memory 300. The mode register value 360 may be indicative of a refresh multiplier (see Table 1). In some examples, the refresh watchdog circuit 315 may receive (e.g., read) the mode register value 360 at a frequency based on Equation 2. The frequency that the mode register 225 is read may be referred to as the ReadInterval. In some examples, the refresh multiplier may be saved in a fourth register (e.g., MR4) of the mode register 225. The refresh multiplier may be stored as a multi-bit value, such as a 5 bit value (e.g., as shown in the example of Table 1, above). Other registers may be used to store the refresh multiplier, and other formats may be used to store the refresh multiplier in other example embodiments.

The refresh watchdog circuit 215 may use a refresh multiplier value (mode register value 360) to calculate the threshold value 370. The threshold value 370 may be a total number of refreshes per cycle (e.g., 8192 ABR commands) divided by the refresh multiplier. In some embodiments, the threshold determination circuit 355 may include a mapping table, and may determine the threshold value 370 using the content of the mode register value 360. For example, the content of the mode register value 360 may be used as a pointer to a register value of the mapping table of the threshold determination circuit 355. The threshold determination circuit 355 may include multiple entries mapping mode register values to respective registers that include threshold values. Additionally or alternatively, using a received refresh multiplier, the threshold determination circuit 355 may calculate a threshold value by dividing a number of refresh commands expected per tREFW (e.g., 8192 ABR commands) by the refresh multiplier value (which indicates a length of tREFW). In some cases, the registers that include the threshold values may correspond to the calculation (e.g., dividing a number of refresh commands (e.g., 8192) by the refresh multiplier value) plus or minus an adjustment amount.

Timing signal 345 may start the comparator 365. The timing signal 345 may include an interrupt signal (e.g., Int32). Comparator 365 may receive the threshold value 370 from the threshold determination circuit 355, and may receive the actual count 375 from the command counter 340. The preset signal 392 from the timer circuit 340 may be provided to the threshold determination circuit 355 and used to load the threshold value 370 to the comparator 365. The preset signal 392 may be provided to the command counter 330 and used to reset the command counter 330 to zero. The comparator 365 may compare the actual count 375 of refresh commands, to the threshold value 370 of refresh commands. If the actual count 375 of refresh commands is less than the threshold value 370 of refresh commands (or, generally, does not meet or exceed the threshold value 370 in the direction counted), the comparator 365 may provide an alert signal 380 to set a state of an alert flag (e.g., a bit) at mode register 325, indicating that there is an error at a memory controller (not pictured) not providing enough refresh commands. In some cases, the preset signal 392 from the timer circuit 340 may update the alert flag at the mode register 325. In this way, the comparator 365 may perform a comparison every period between timing signals 345 (e.g., every 32 ms between signals Int32).

In some examples, comparator 365 may provide a real time flag (e.g., to a dedicated alert pin, or a multi-function pin, or any other way the memory communicates with the controller). For example, comparator 365 may provide the real time flag to a controller, or to any other device. In some examples, the flag may be transmitted asynchronously back to a host device or added into a synchronous protocol. In some examples, the real time flag may be a subset of a different (e.g., existing) error notification, such as a master error flag. In such embodiments, the controller may check one or more error registers of the memory responsive to the master error flag to determine a nature of the error. Receiving the real time flag may be desirable in safety-critical applications where receiving timely notifications of low refresh rates is desirable.

Such examples for providing the real time flag to a pin may also be more accessible than accessing a mode register (e.g., the alert flag at the mode register 325), such as in lab testing scenarios. For example, an integrator could subject the memory to temperature variations and monitor the pin for the real time flag to confirm that a memory controller is issuing refresh commands at a sufficient rate for a given temperature.

In some examples, the timer circuit 340 may provide the preset signal 392, the timing signal 345, or both, based on a voltage controlled oscillator circuit 385. The voltage controlled oscillator circuit 385 may be stabilized against variations of various processes, memory supply voltage, temperature, and/or other factors. The voltage controlled oscillator circuit 385 may provide a clock signal 390, which may have a known, stable, and in some cases trimmable, frequency to the timer circuit 340.

In some examples, mode register 325 may include information (e.g., one additional mode register bit) to track if a register of mode register 325 (e.g., an MR4 register) access to the mode register value 360 occurred during the past evaluation period (e.g., during the last period defined by the period between timing signals 345 (e.g., 32 ms). In some examples, mode register 325 may include one additional mode register bit to flag if additional Refresh Management processes took place during the past evaluation period. In some examples, mode register 325 may include one bit (e.g., switch) to switch from a 32 ms evaluation period, or any other evaluation period, to a 4 ms period, or any other different evaluation period.

In some examples, mode register 325 may include a switch (e.g., one bit to switch) from an ABR mode to a single-bank refresh mode (e.g., may be referred to as a PBR mode). In this way, refresh watchdog circuit 315 may be able to toggle between monitoring for PBR commands vs ABR commands, or between any other commands. The switching modes feature may be based on the device bank architecture configuration (e.g., how many banks are present in the device at the actual device configuration (e.g., 4, 8, or 16 for LP5 DRAM)). In using different modes, one or more features of the present invention may be altered slightly (e.g., in setting threshold value 370), but one with ordinary skill in the art would appreciate that operating in the different modes does not depart from the central aspects of the present invention. For example, for a PBR mode, setting the threshold value 370 by the threshold determination circuit 355 may involve using a different look up table for mapping the mode register value 360 to a register out of a look up table array, or the registers may have different values. In some other examples, threshold determination circuit 355 may calculate the threshold value 370 by dividing the number of issued PBR commands to memory by the refresh multiplier value, rather than dividing 8192 commands as per an ABR mode by the refresh multiplier value.

In some examples, the timer circuit 340 may be based on a CK external clock frequency, an ICLK internal clock frequency, or any other clock frequency. For the timer circuit 340 being based on the CK external clock frequency, the mode register 325 may include an additional register to be programmed by frequency information, and memory 300 may include a programmable clock divider.

FIG. 4 is a block diagram of a vehicle 405 in accordance with examples described herein. Vehicle 405 may include a system on chip (SoC), which may include a controller 435 and a memory 440. In some examples, controller 435 may correspond to memory controller 210, and memory 440 may correspond to memory 205. Vehicle 405 may include an input/output (I/O) 410. Vehicle 405 may include automotive systems 415, which may include engine 425 and other systems 430. Other systems 430 may include systems such as infotainment systems, drivetrain systems, climate control systems, lighting systems, and the like.

Memory 440 (e.g., using a refresh watchdog circuit) may detect that controller 435 is not providing refresh commands at an expected rate in accordance with previous examples. Detecting when the memory controller is not providing refresh commands at the expected rate allows for troubleshooting on controller 435 so that data in memory cells in a memory array of memory 440 is not lost due to insufficient refreshing at high temperatures.

Such detection may be particularly useful in automotive scenarios. For example, automotive makers may be using electronic equipment (e.g., controller 435) with faulty refresh settings, which may result in insufficient refresh commands provided to the memory 440. Faulty refresh settings can lead to increased bit error rates causing problems like decrease in quality of service, system failures, or execution of incorrect opcodes. Detecting such faulty refresh settings may be beneficial for enhancing automotive reliability, ensuring safe operation, etc.

The controller 435 may take various actions upon discovering that the memory 440 has determined that the rate of refresh commands does not meet the expected refresh rate (e.g., either on reading the alert mode register and/or upon receiving the alert signal). For example, the controller 435 may check the refresh multiplier in the memory 440 and adjust the rate of refresh commands provided accordingly, may initiate an error check of information stored in the memory 205, may increase a frequency at which the refresh multiplier is checked (and the refresh rate adjusted), may take other actions (e.g., alerting a user via I/O 410 or one or more other systems 430 such as an infotainment system), or combinations of these. In some examples, upon discovering that the rate of refresh commands does not meet the expected refresh rate, controller 435 may communicate with one or more automotive systems 415 to cause the vehicle 405 to pull over to the side of the road and/or park the vehicle 405 (e.g., in partially or fully automated vehicles 405), slow down, turn on blinkers, or any other actions.

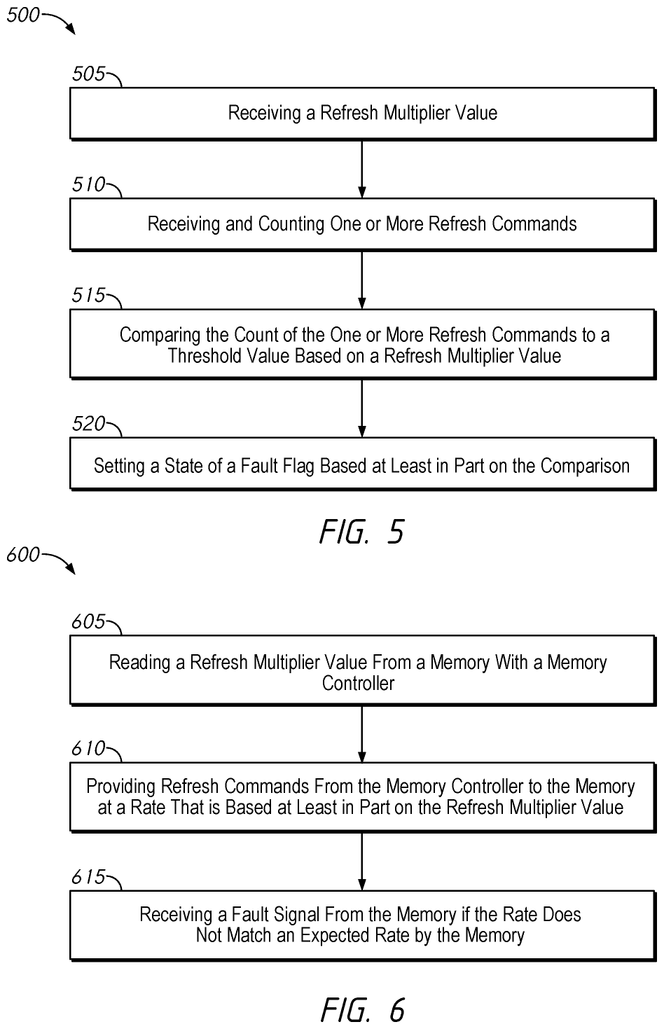

FIG. 5 is a flowchart of a method 500 in accordance with examples described herein. Method 500 may be implemented using, for example, semiconductor device 100, semiconductor device 200, memory 300, or memory 440 in FIG. 1, 2, 3, or 4, respectively, or any combination of those depicted in FIG. 1, 2, 3, or 4.

At 505, the method may include receiving a refresh multiplier value (e.g., 260, 360). The refresh multiplier value may be stored in a mode register (e.g., 128 of FIG. 1, 230 of FIG. 2. 325 of FIG. 3), or may be indicative of a value stored in the mode register. The method 400 may include measuring a temperature of the memory (e.g., device 100, memory 205) and setting a value of the refresh multiplier in the mode register based on the measured temperature.

At 510, the method may include receiving and counting one or more refresh commands (e.g., 255, 393). In some examples, the method may include receiving a first timing signal and a second timing signal (e.g., subsequent timing signals 345), wherein a first time period comprises a time between the first timing signal and the second timing signal, and wherein receiving and counting the quantity of refresh commands occurs within the first time period. In some examples, the first timing signal and the second timing signal are based at least in part on a clock signal (e.g., 390).

At 515, the method may include comparing the count of the one or more refresh commands to a threshold value based on a refresh multiplier value. In some examples, the threshold value is based at least in part on a constant value and the received refresh multiplier value. In some examples, the method may include calculating the threshold value by dividing a constant value by the refresh multiplier value. In some examples, the method may include determining the threshold value by accessing a table (e.g., at 355) that maps the refresh multiplier value to the threshold value. In some examples, the refresh multiplier value is inversely proportional to a refresh rate.

At 520, the method may include setting a state of a fault flag based at least in part on the comparison. In some examples, the method may include providing a real time flag to a pin based at least in part on the comparison.

FIG. 6 is a flowchart of a method 600 in accordance with examples described herein. Method 600 may be implemented using, for example, memory controller 210 or controller 435 of FIG. 2 and FIG. 4, respectively.

At 605, the method may include reading a refresh multiplier value from a memory with a memory controller.

At 610, the method may include providing refresh commands (e.g., 255) from the memory controller to the memory at a rate that is based at least in part on the refresh multiplier value (e.g., 260).

At 615, the method may include receiving a fault signal (e.g., 270) from the memory if the rate does not match an expected rate by the memory. In some examples, the method may include indicating an error responsive to the fault signal. In some examples, the method may include periodically checking a mode register of the memory for a fault flag. In some examples, the method may include receiving a real time flag from a pin if the rate does not match an expected rate by the memory. In some examples, the method may include changing the rate of providing the refresh commands responsive to receiving the fault signal.

As used herein, an activation of a signal may refer to any portion of a signals waveform that a circuit responds to. For example, if a circuit responds to a rising edge, then a signal switching from a low level to a high level may be an activation. One example type of activation is a pulse, where a signal switches from a low level to a high level for a period of time, and then back to the low level. This may trigger circuits which respond to rising edges, falling edges, and/or signals being at a high logical level. One of skill in the art should understand that although embodiments may be described with respect to a particular type of activation used by a particular circuit (e.g., active high), other embodiments may use other types of activation (e.g., active low).

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a command counter circuit configured to count a first quantity of refresh commands;
a threshold determination circuit configured to set a threshold quantity of target refresh commands based on a refresh multiplier value;
a comparator circuit configured to receive the first quantity from the command counter, receive the threshold quantity from the threshold determination circuit, compare the first quantity to the threshold quantity, and set a state of a fault flag based at least in part on the comparison.

2. The apparatus of claim 1, wherein the command counter circuit is configured to count the first quantity of refresh commands performed within a first time period, and wherein the threshold determination circuit is configured to store the second quantity of target refresh commands performed within the first time period, and wherein the first time period is based at least in part on a timer circuit.

3. The apparatus of claim 1, wherein the threshold determination circuit is configured to calculate the threshold quantity of target refresh commands by dividing the constant value by the refresh multiplier value.

4. The apparatus of claim 1, wherein the threshold determination circuit comprises a table configured to map the refresh multiplier value to the threshold quantity of target refresh commands.

5. The apparatus of claim 1, wherein the command counter circuit and the threshold determination circuit are configured to be reset by a preset signal from a timer circuit.

6. The apparatus of claim 1, wherein the refresh multiplier value is based at least in part on a temperature of a memory device comprising the apparatus.

7. The apparatus of claim 1, further comprising a pin configured to couple the apparatus to an external controller, wherein the comparator circuit is configured to provide a real time flag to the pin based at least in part on the comparison.

8. A memory, comprising:
a mode register comprising a first register and a second register, the first register configured to store a refresh multiplier value, wherein the refresh multiplier value is based at least in part on a temperature of the memory, and the second register configured to store a fault flag; and
a refresh watchdog circuit configured to:
receive the refresh multiplier value from the mode register,
determine a threshold value based on the refresh multiplier value,
receive and count a quantity of refresh commands,
compare the count of the one or more refresh commands to the threshold value, and
set a state of the fault flag based at least in part on the comparison.

9. The memory of claim 8, further comprising:
a timer circuit configured to provide a first timing signal and a second timing signal to the refresh watchdog circuit, wherein a first time period comprises a time between the first timing signal and the second timing signal, and wherein the refresh watchdog circuit is configured to receive and count the quantity of refresh commands within the first time period.

10. The memory of claim 9, further comprising:
an oscillator circuit configured to provide a clock signal to the timer circuit, wherein the timer circuit providing the first timing signal and the second timing signal is based at least in part on the clock signal.

11. The memory of claim 8, wherein the refresh watchdog circuit is configured to calculate the threshold value by dividing a constant value by the refresh multiplier value.

12. The memory of claim 8, wherein the refresh watchdog circuit is configured to determine the threshold value by accessing a table that maps the refresh multiplier value to the threshold value.

13. The memory of claim 8, wherein the refresh multiplier value is inversely proportional to a refresh rate.

14. A method, comprising:
receiving a refresh multiplier value;
receiving and counting one or more refresh commands;
comparing the count of the one or more refresh commands to a threshold value based on a refresh multiplier value; and
setting a state of a fault flag based at least in part on the comparison.

15. The method of claim 14, further comprising:
receiving a first timing signal and a second timing signal, wherein a first time period comprises a time between the first timing signal and the second timing signal, and wherein receiving and counting the quantity of refresh commands occurs within the first time period.

16. The method of claim 14, further comprising:
measuring a temperature of a memory; and
setting a value of the refresh multiplier based on the measured temperature.

17. The method of claim 14, further comprising:
calculating the threshold value by dividing a constant value by the refresh multiplier value.

18. The method of claim 14, further comprising:
determining the threshold value by accessing a table that maps the refresh multiplier value to the threshold value.

19. The method of claim 14, wherein the refresh multiplier value is inversely proportional to a refresh rate.

20. The method of claim 14, further comprising:
providing a real time flag to a pin based at least in part on the comparison.
